(19) United States
(12) Patent Application Publication
(10) Pub. No.: US 2015/0363309 A1
(43) Pub. Date: Dec. 17, 2015

(54) SYSTEM AND METHOD OF INCREASING RELIABILITY OF NON-VOLATILE MEMORY STORAGE

(71) Applicant: KingTiger Technology (Canada) Inc., Markham (CA)

(72) Inventors: Bosco Chun Sang Lai, Markham (CA); Sunny Lai-Ming Chang, Markham (CA); Alexei Krouglov, Markham (CA); Eric Sin Kwok Chiu, Mississauga (CA)

(21) Appl. No.: 14/742,085

(22) Filed: Jun. 17, 2015

Related U.S. Application Data
(60) Provisional application No. 62/013,466, filed on Jun. 17, 2014.

(51) Int. Cl. G06F 12/02; G11C 29/02

(52) U.S. Cl. CPC G06F 12/0246; G11C 29/022; G06F 2212/7201

(57) ABSTRACT

Various embodiments are described herein for a system and a method for increasing reliability of a secondary storage device used with a computing system where the secondary storage device contains a memory buffer, a controller, and non-volatile memory. The method may comprise initializing a test of the memory buffer; testing at least one memory block of the memory buffer; discontinuing use of a given memory block of the memory buffer if a defective memory location is detected for the given memory block; and storing test results for the memory buffer.

### CROSS-REFERENCE TO RELATED APPLICATION

This application claims the benefit and priority of U.S. Provisional Patent Application Ser. No. 62/013,466, filed on Jun. 17, 2014. The entire contents of such application are hereby incorporated by reference.

### FIELD

Various embodiments are described herein that generally relate to computing systems that utilize memory and a method for testing memory.

### BACKGROUND

A computing system generally includes hardware components and corresponding software components or programs that are used to control the hardware and have the computing system operate in a certain manner. The software components include an operating system that manages the operation of the programs that are run on the computer to have it do certain tasks. The computing system employs main memory to store the programs; however, the computing system typically includes secondary storage such as non-volatile memory to store data and/or programs used during operation. The non-volatile memory may include one or more of hard disks, flash memories, and solid-state drives, for example. In conventional computing systems, the amount of such secondary storage utilized by the computing system may be on the order of gigabytes and terabytes.

As a rule, the secondary storage contains a non-volatile memory element, a memory buffer (which is sometimes called a disk cache or a cache buffer) and a controller that controls the operation of the non-volatile memory and the memory buffer. The memory buffer serves to align the speed of the computer system's main memory and the speed of the non-volatile memory. The memory buffers inside a secondary storage are usually built using DRAM technology. Testing for memory failures in the secondary storage conventionally comprises testing for memory failures in the non-volatile memory that may be detected by using an error-correcting code mechanism.

### SUMMARY OF VARIOUS EMBODIMENTS

In a broad aspect, at least one embodiment described herein provides a method of increasing reliability of a secondary storage device used with a computing system where the secondary storage device contains a memory buffer, a controller, and non-volatile memory, the method comprising initializing a test of the memory buffer; testing at least one memory block of the memory buffer; discontinuing use of a given memory block of the memory buffer if a defective memory location is detected for the given memory block; and storing test results for the memory buffer.

In at least one embodiment, discontinuing use of the given memory block having a defective memory location may comprise removing the given memory block containing the defective memory location from a list of accessible memory blocks for the memory buffer and storing the list in the buffer memory and/or the non-volatile memory of the secondary storage device.

In at least one embodiment, discontinuing use of the given memory block having a defective memory location may comprise adding the given memory block to a list of inaccessible memory blocks for the memory buffer and storing the list of inaccessible memory blocks in the buffer memory and/or the non-volatile memory of the secondary storage device.

In at least one embodiment, the acts of testing, detecting and discontinuing use are performed by the controller of the secondary storage device.

In at least one embodiment, firmware used by the controller may be configured to perform the acts of testing, detecting and discontinuing use.

In at least one embodiment, the memory buffer may comprise a mapping table that maps memory blocks of the memory buffer to memory blocks of the non-volatile memory and the method may further comprise removing a reference to memory blocks having defective memory locations from the mapping table.

In at least one embodiment, the memory buffer may comprise a mapping table that maps memory blocks of the memory buffer to memory blocks of the non-volatile memory and the method may further comprise marking references in the mapping table to memory blocks having defective memory locations as being the most recently used memory blocks and mapping the memory blocks having defective memory locations to a non-existent memory block of the non-volatile memory.

In a broad aspect, at least one embodiment described herein provides a secondary storage device for providing memory storage space for a computing system, wherein the secondary storage device comprises a non-volatile memory configured to store data; a memory buffer coupled to the non-volatile memory and a main memory of the computing system, the memory buffer being configured to act as a disk cache between the non-volatile memory and main memory of the computing system; and a controller coupled to the non-volatile memory and the memory buffer, the controller being configured to test the memory buffer for errors by initializing a test of the memory buffer; testing at least one memory block of the memory buffer; discontinuing use of a given memory block of the memory buffer if a defective memory location is detected for the given memory block; and storing test results for the memory buffer.

In at least one embodiment, the controller may be configured to discontinue use of the given memory block having a defective memory location by removing the given memory block containing the defective memory location from a list of accessible memory blocks for the memory buffer and storing the list in the buffer memory and/or the non-volatile memory of the secondary storage device.

In at least one embodiment, discontinuing use of the given memory block having a defective memory location may comprise adding the given memory block to a list of inaccessible memory blocks for the memory buffer and storing the list of inaccessible memory blocks in the buffer memory and/or the non-volatile memory of the secondary storage device.

In at least one embodiment, the memory buffer may comprise a mapping table that maps memory blocks of the memory buffer to memory blocks of the non-volatile memory and the controller is configured to remove the reference to memory blocks having defective memory locations from the mapping table.

In at least one embodiment, the memory buffer may comprise a mapping table that maps memory blocks of the memory buffer to memory blocks of the non-volatile memory and the controller may be configured to mark references in the mapping table to memory blocks having defective memory locations as being the most recently used memory blocks and mapping the memory blocks having defective memory locations to a non-existent memory block of the non-volatile memory.

In at least one embodiment, the non-volatile memory may comprise at least one of flash memory, a solid-state drive and a hard drive.

In a broad aspect, at least one embodiment described herein provides a computing system that may comprise: a Central Processing Unit (CPU) to control the computing system; a main memory element coupled to the CPU to store information used by the CPU during the operation of the computing system; and a secondary storage device for providing memory storage space for a computing system, wherein the secondary storage device may comprise: a non-volatile memory configured to store data; a memory buffer coupled to the non-volatile memory and a main memory of the computing system, the memory buffer being configured to act as a disk cache between the non-volatile memory and main memory of the computing system; and a controller coupled to the non-volatile memory and the memory buffer. The controller may be configured to test the memory buffer for errors by initializing a test of the memory buffer; testing at least one memory block of the memory buffer; discontinuing use of a given memory block of the memory buffer if a defective memory location is detected for the given memory block; and storing test results for the memory buffer.

In at least one embodiment of the computing system, discontinuing use of the given memory block having a defective memory location may comprise adding the given memory block to a list of inaccessible memory blocks for the memory buffer and storing the list of inaccessible memory blocks in the buffer memory or the non-volatile memory of the secondary storage device.

In a broad aspect, at least one embodiment described herein provides a computer readable medium comprising a plurality of instructions that are executable by a controller of a secondary storage device for increasing reliability of the secondary storage device, the secondary storage device further comprising a memory buffer and non-volatile memory both coupled to the controller, wherein the plurality of instructions implement a method comprising: initializing a test of the memory buffer; testing at least one memory block of the memory buffer; discontinuing use of a given memory block of the memory buffer if a defective memory location is detected for the given memory block; and storing test results for the memory buffer in the non-volatile memory, the test results being used by the controller to avoid defective memory locations for future read and write operations.

In at least one embodiment of the computer readable medium, discontinuing use of the given memory block having a defective memory location may comprise removing the given memory block containing the defective memory location from a list of accessible memory blocks for the memory buffer and storing the list in the buffer memory and/or the non-volatile memory of the secondary storage device.

In at least one embodiment of the computer readable medium, discontinuing use of the given memory block having a defective memory location may comprise adding the given memory block to a list of inaccessible memory blocks for the memory buffer and storing the list of accessible memory blocks in the buffer memory and/or the non-volatile memory of the secondary storage device.

In at least one embodiment of the computer readable medium, the acts of testing, detecting and discontinuing use may be performed by the controller of the secondary storage device.

In at least one embodiment of the computer readable medium, the memory buffer may comprise a mapping table that maps memory blocks of the memory buffer to memory blocks of the non-volatile memory and the method further comprises removing the reference to memory blocks having defective memory locations from the mapping table.

In at least one embodiment of the computer readable medium, the memory buffer comprises a mapping table that maps memory blocks of the memory buffer to memory blocks of the non-volatile memory and the method further comprises marking references in the mapping table to memory blocks having defective memory locations as being the most recently used memory blocks and mapping the memory blocks having defective memory locations to a non-existent memory block of the non-volatile memory.

Other features and advantages of the present application will become apparent from the following detailed description taken together with the accompanying drawings. It should be understood, however, that the detailed description and the specific examples, while indicating one or more embodiments of the application, are given by way of illustration only, since various changes and modifications within the spirit and scope of the application will become apparent to those skilled in the art from this detailed description.

### BRIEF DESCRIPTION OF THE DRAWINGS

For a better understanding of the various embodiments described herein, and to show more clearly how these various embodiments may be carried into effect, reference will be made, by way of example, to the accompanying drawings which show at least one example embodiment, and which are now described. The drawings are not intended to limit the scope of the teachings described herein.

FIG. 1 is a block diagram of an example embodiment of a computing system having a secondary storage device in which the arrows indicate data flow.

FIG. 2 is a block diagram of an example usage scenario for the secondary storage device in which there is an error in the memory space of the memory buffer and the arrows indicate data flow.

FIG. 3 is a flowchart of an example embodiment of a method for testing the memory buffer of the secondary storage device for memory errors.

FIG. 4 is a block diagram of an example usage scenario for testing the memory buffer of the secondary storage device for errors and dealing with the errors in which the arrows indicate data flow.

Further aspects and features of the example embodiments described herein will appear from the following description taken together with the accompanying drawings.

### DETAILED DESCRIPTION OF THE EMBODIMENTS

Various systems, devices or methods will be described below to provide an example of at least one embodiment of the claimed subject matter. No embodiment described herein limits any claimed subject matter and any claimed subject matter may cover systems, devices or methods that differ from those described herein. The claimed subject matter is not limited to systems, devices or methods having all of the features of any one process or device described below or to features common to multiple or all of the systems, devices or methods described herein. It is possible that a system, device or method described herein is not an embodiment of any claimed subject matter. Any subject matter that is disclosed in a system, device or method described herein that is not claimed in this document may be the subject matter of another protective instrument, for example, a continuing patent application, and the applicants, inventors or owners do not intend to abandon, disclaim or dedicate to the public any such subject matter by its disclosure in this document.

Furthermore, it will be appreciated that for simplicity and clarity of illustration, where considered appropriate, reference numerals may be repeated among the figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, well-known methods, procedures and components have not been described in detail so as not to obscure the embodiments described herein. Also, the description is not to be considered as limiting the scope of the embodiments described herein.

It should also be noted that the terms “coupled” or “coupling” as used herein can have several different meanings depending in the context in which these terms are used. For example, the terms coupled or coupling can have a mechanical, electrical or communicative connotation. For example, as used herein, the terms coupled or coupling can indicate that two or more elements or devices can be directly connected to one another or connected to one another through one or more intermediate elements or devices via an electrical element, electrical signal or a mechanical element depending on the particular context. Furthermore, the term “communicative coupling” indicates that an element or device can electrically, or wirelessly send data to or receive data from another element or device depending on the particular embodiment.

It should also be noted that, as used herein, the wording “and/or” is intended to represent an inclusive-or. That is, “X and/or Y” is intended to mean X or Y or both, for example. As a further example, “X, Y, and/or Z” is intended to mean X or Y or Z or any combination thereof.

It should also be noted that terms of degree such as “substantially”, “about” and “approximately” as used herein mean a reasonable amount of deviation of the modified term such that the end result is not significantly changed. These terms of degree may also be construed as including a deviation of the modified term if this deviation would not negate the meaning of the term it modifies.

Furthermore, the recitation of numerical ranges by endpoints herein includes all numbers and fractions subsumed within that range (e.g., 1 to 5 includes 1, 1.5, 2, 2.75, 3, 3.90, 4, and 5). It is also to be understood that all numbers and fractions thereof are presumed to be modified by the term “about”, which means a variation of up to a certain amount of the number to which reference is being made if the end result is not significantly changed, such as 10%, for example.

The example embodiments of the systems, devices or methods described in accordance with the teachings herein may be implemented as a combination of hardware or software. For example, the embodiments described herein may be implemented, at least in part, by using one or more computer programs, executing on one or more programmable devices comprising at least one processing element, and at least one data storage element (including volatile and non-volatile memory and a memory buffer). These devices may also have at least one input device (e.g., a keyboard, a mouse, a touchscreen, and the like), and at least one output device (e.g., a display screen, a printer, a wireless radio, and the like) depending on the nature of the device.

It should also be noted that there may be some elements that are used to implement at least part of the embodiments described herein that may be implemented via software that is written in a high-level procedural language such as object oriented programming. The program code may be written in C, C⁺⁺ or any other suitable programming language and may comprise modules or classes, as is known to those skilled in object oriented programming. Alternatively, or in addition thereto, some of these elements implemented via software may be written in assembly language, machine language or firmware as needed.

At least some of these software programs may be stored on a storage media (e.g., a computer readable medium such as, but not limited to, ROM, magnetic disk, optical disc) or a device that is readable by a general or special purpose programmable device. The software program code, when read by the programmable device, configures the programmable device to operate in a new, specific and predefined manner in order to perform at least one of the methods described herein.

Furthermore, at least some of the programs associated with the systems and methods of the embodiments described herein may be capable of being distributed in a computer program product comprising a computer readable medium that bears computer usable instructions, such as program code, for one or more processors. The program code may be preinstalled and embedded during manufacture and/or may be later installed as an update for an already deployed computing system. The medium may be provided in various forms, including non-transitory forms such as, but not limited to, one or more diskettes, compact disks, tapes, chips, and magnetic and electronic storage. In alternative embodiments, the medium may be transitory in nature such as, but not limited to, wire-line transmissions, satellite transmissions, internet transmissions (e.g. downloads), media, digital and analog signals, and the like. The computer useable instructions may also be in various formats, including compiled and non-compiled code.

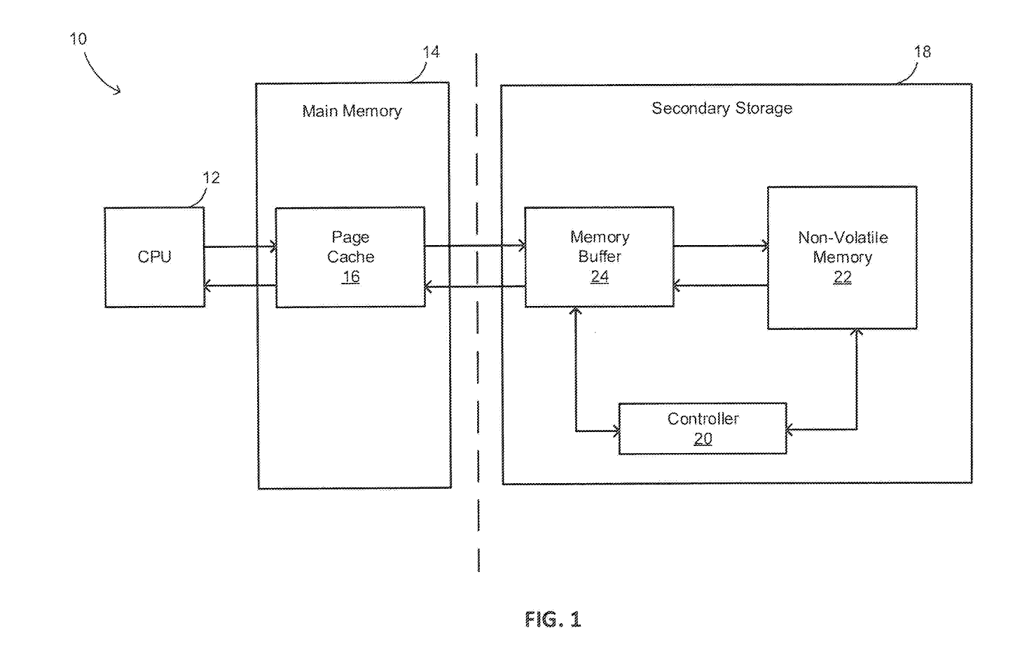

Referring now to FIG. 1, shown therein is a block diagram of an example embodiment of a computing system 10 having a secondary storage device 18. FIG. 1 provides an example of how the data from the secondary storage device 18 propagates through the computing system 10 (the arrows in FIG. 1 indicate data flow).

The computing system 10 comprises a Central Processing Unit (CPU)12, a main memory element 14 having a page cache 16 and a secondary storage device 18 having a controller 20, non-volatile memory 22 and a memory buffer 24. The computing device 10 may be used in a variety of applications ranging from a stand-alone electronic device that is configured to perform certain functions such as a smart phone, for example, to a server that may be used to control a network of computers.

The secondary storage device 18 may be in a common physical housing with the CPU 12 and the main memory element 14 or the secondary storage device 18 may be in a separate physical housing compared to the CPU 12 and the main memory element 14. These different embodiments are shown by the use of a vertical dashed line in FIG. 1.

The CPU 12 controls the operation of the computing system 10 and can be any suitable processor, controller or digital signal processor that can provide sufficient processing power depending on the configuration and operational requirements of the computing system 10. For example, the CPU may be a high performance general processor. In alternative embodiments, the CPU 12 may include more than one processor with each processor being configured to perform different dedicated tasks. In alternative embodiments, specialized hardware, like an Application Specific Integrated Circuit (ASIC) or a Field Programmable Gate Array (FPGA), for example, may be used to provide some of the functions provided by the CPU 12.

The main memory 14 is used to store information that is used by the CPU 12 during the operation of the computing system 10. For this purpose, the main memory 14, which may typically be Random Access Memory (RAM), may include a page cache 16 that may be used by the CPU 12 to access data more quickly than is possible from the secondary storage 18. Accordingly, the page cache 16 may be used to store software instructions or data that are frequently used by a program and the fast access provided by the page cache 16 may result in the software instructions being executed faster. The same data may be read from a page cache 16 several times or there may be a high likelihood that multiple READ and WRITE operations may be combined in a single larger memory block (i.e., the page cache 16). A memory block may be considered to be a contiguous memory address space.

The secondary storage device 18 comprises non-volatile memory 22 that may not be directly accessed by the CPU 12. Various communication channels or busses may be used to transfer data between the CPU 12 and the secondary storage device 18. The non-volatile memory 22 does not lose the stored data when the computing system 12 is powered down. The computing system 10 may have a different amount of memory space in the secondary storage device 18 compared to the main memory 14 and data is stored for a longer period of time in the secondary storage device 18.

The non-volatile memory 22 of the secondary storage device 18 may include, but is not limited to, a hard disk drive, an optical storage device such as a CD or DVD drive, flash memory such as USB flash drives, USB keys and solid state drives, for example. The non-volatile memory 22 may also comprise several memory elements that may be accessed in parallel to increase speed.

The memory buffer 24, which may called a disk cache or cache buffer, serves to align the speed of the main memory 14 of the computing system 10 and the speed of the non-volatile memory 22. The memory buffer 24 may be built using DRAM technology or another suitable RAM technology such as, but not limited to SRAM, for example.

The controller 20 controls the operation of the non-volatile memory 22 and the memory buffer 24 including data transfer between these elements. The implementation of the controller 20 depends on the type of memory used for the non-volatile memory 22. For example, when the non-volatile memory 22 comprises flash memory, a solid state drive or a hard disk, then the controller 20 may be a flash controller, an SSD controller or a disk controller, respectively. The controller 20 may perform various functions such as, but not limited to ECC and wear leveling, for example.

When the CPU 12 needs to access and read data that is stored inside the non-volatile memory 22, the CPU may first check if the desired data is already stored inside the page cache 16 of the main memory 14. If the desired data is in the page cache 16, then the CPU 12 may read the desired data. If the desired data is not in the page cache 16, the CPU 12 may check if the desired data is stored inside the memory buffer 24 located inside the secondary storage device 18. If the desired data is in the memory buffer 24, then the desired data is sent from the memory buffer 24 to the page cache 16 and the CPU 12 then reads the desired data from the page cache 16. If the desired data is not in the memory buffer 24 then the desired data is sent from the non-volatile memory 22 to the memory buffer 24, and then sent from the memory buffer 24 to the page cache 16 after which the CPU 12 may read the desired data from the page cache 16.

When the CPU 12 needs to access and modify data stored inside the non-volatile memory 22, it may first check if there is storage of the needed data inside the page cache 16 located inside main memory 14. If the desired data is stored in the page cache 16, the CPU 12 may then modify the desired data. If the desired data is missing from the page cache 16 the CPU 12 may then check if the desired data is stored in the memory buffer 24 located inside the secondary storage device 18. If the desired data is stored in the memory buffer 24, then the desired data is propagated from the memory buffer 24 to the page cache 16 and the CPU 12 may then modify the desired data in the page cache 16. If the desired data is not stored in the memory buffer 24, the desired data is propagated from the non-volatile memory 22 to the memory buffer 24, and then the data is propagated from the memory buffer 24 to the page cache 16 and the CPU 12 may then modify the desired data in the page cache 16.

Before data is sent or propagated from the memory buffer 24 to the page cache 16, the CPU 12 may perform a check of the page cache 16 to see if there is enough memory space in the page cache 16 to store the data. If there is not enough memory space inside the page cache 16, some portion of data from the page cache 16 may be sent back to the memory buffer 24 to free the needed memory space in the page cache 16. There are some algorithms that are known to those skilled in the art which may be used to choose what portion of data is sent back from the page cache 16 to the memory buffer 24. For example, the portion of data that was least recently accessed inside the page cache 16 may be sent back to the memory buffer 24. Additionally, the CPU 12 may also check to see if the portion of data that will be sent from the page cache 16 to the memory buffer 24 was previously modified. If the portion of the data that is being sent from the page cache 16 to the memory buffer 24 was previously modified, the data is sent back to the memory buffer 24. If the portion of data that is sent from the page cache 16 to the memory buffer 24 was not modified it is discarded since the memory buffer 24 contains an exact copy of that portion of data. The memory management unit of the CPU 12 may control the data flow described in this paragraph.

When data is propagated from the non-volatile memory 22 to the memory buffer 24 there is a check by the controller 20 to determine if the memory buffer 22 has enough memory space to store the data. If there is not enough memory space inside the memory buffer 24 to store this data, some portion of the data from the memory buffer 24 is sent back to the non-volatile memory 22 to free up some memory space in the memory buffer 24. There are some algorithms that are known to those skilled in the art that may be used to choose what portion of data to send back from the memory buffer 24 to the non-volatile memory 22. For example, the portion of data that was least recently accessed inside the memory buffer 24 may be sent back to the non-volatile memory 22. In some embodiments, the controller 20 may perform an additional check to determine if the portion of data to send back from the memory buffer 24 to the non-volatile memory 22 was previously modified. If this portion of data was previously modified then it may be sent back to the non-volatile memory 22. If this portion of data was not modified then it may be discarded since the non-volatile memory 22 contains an exact copy of that portion of data. The controller 20 controls the data flow described in this paragraph.

The data transferred between the page cache 16 and the memory buffer 24 and the data transferred between the memory buffer 24 and the non-volatile memory 22 may be part of larger memory blocks or memory pages that are transferred between these elements. Alternatively, this data may be transferred in smaller blocks.

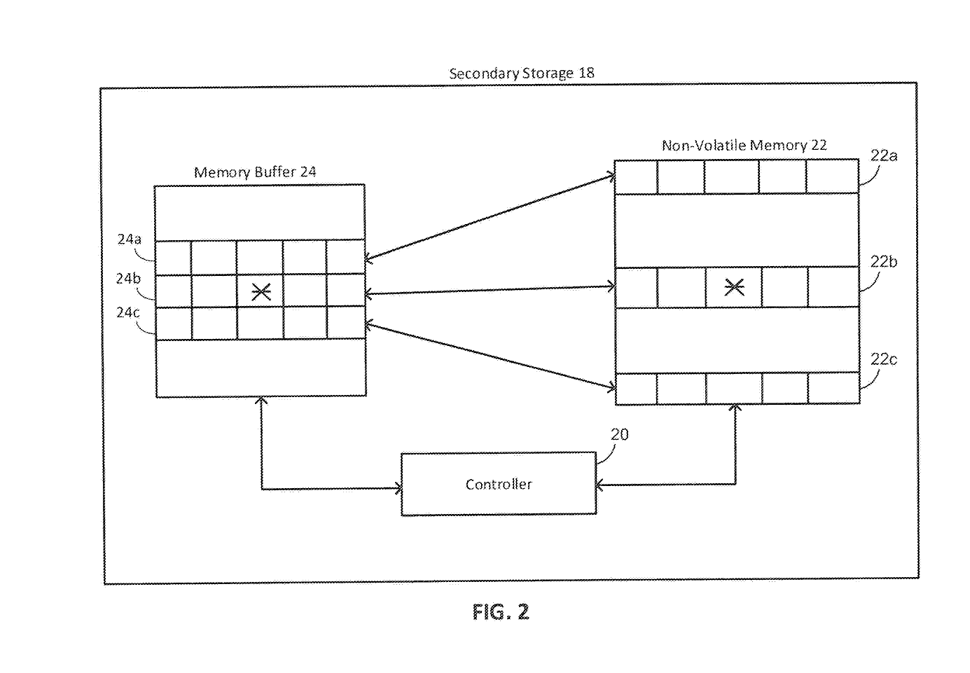

Referring now to FIG. 2, shown therein is a block diagram of an example usage scenario for the secondary storage device 18 in which there is an error in the memory space of the memory buffer 24. FIG. 2 provides an example of how memory blocks inside the memory buffer 24 may be mapped to memory blocks inside the non-volatile memory 22 (the arrows in FIG. 2 indicate data flow). The term “memory block” is meant to cover various sections of memory including, but not limited to, a memory page or a contiguous memory address space consisting of a row, a half-row, or some other grouping of memory cells within an individual memory device, on one or more memory devices.

In this example usage scenario, the memory buffer 24 comprises three memory blocks 24a, 24b and 24c. The non-volatile memory 22 includes three memory blocks 22a, 22b and 22c that correspond to the memory blocks 24a, 24b and 24c of the memory buffer 24. It is assumed that the memory block 24b has experienced a memory failure (represented by the asterisk) which means that any data that is stored inside memory block 24b will probably get corrupted.

As noted earlier, data from the memory buffer 24 may occasionally be sent back to the non-volatile memory 22 in order to free up memory space in the memory buffer 24. However, this action may send the corrupted data from the memory block 24b of the memory buffer 24 to the corresponding memory block 22b of the non-volatile memory 22. As a result, the data inside the memory block 22b of the non-volatile memory 22 will also be corrupted. Since the operation of sending data from the memory buffer 24 to various sections of the non-volatile memory 22 to free up memory space in the memory buffer 24 may be repeated a number of times, the corrupted data from the memory block 24b may occupy several different memory blocks inside the non-volatile memory 22 and potentially corrupt a large amount of data inside the non-volatile memory 22.

As was previously mentioned, testing for memory failures in the secondary storage device 16 conventionally comprises testing for memory failures in the non-volatile memory 22. These errors may be detected by using an error-correcting mechanism as is known by those skilled in the art such as, but not limited to, Hamming codes or a Cyclic Redundancy Check (CRC), for example. However, in conventional secondary storage devices, the memory buffer 24 is never tested for memory failures. Therefore, as seen in the example of FIG. 2, memory failures that occur in the memory buffer 24 often go undetected which can adversely affect the operation of the computing system 12. Furthermore, since the memory buffer 24 provides a cache-like functionality, corrupted data in the memory buffer 24 may populate or multiply to various portions of the memory space of the non-volatile memory 22. For example, it is possible that a small memory error inside the memory buffer 24 may pollute a big array of data inside the non-volatile memory 22. Furthermore, while an error-correcting mechanism used for the non-volatile memory 22 can correct errors that happen inside the non-volatile memory 22 it cannot correct errors that happen outside of the non-volatile memory 22 (e.g., it cannot correct errors that happen inside the memory buffer 24). This creates a very significant problem in the proper functioning of the secondary storage device 18 with the computing system 10.

In accordance with the teachings of the present application, example embodiments of a method and system are provided herein that may alleviate the problem with potential data pollution caused by memory failures inside the memory buffer of a secondary storage device. In general, these example embodiments may include testing the memory buffer for memory blocks having memory errors and then removing the memory blocks from further usage during the operation of the computing system. For example, in accordance with the teachings herein, the controller 20 inside the secondary storage device 18 may be used to detect if any memory failures occur inside the memory buffer 24.

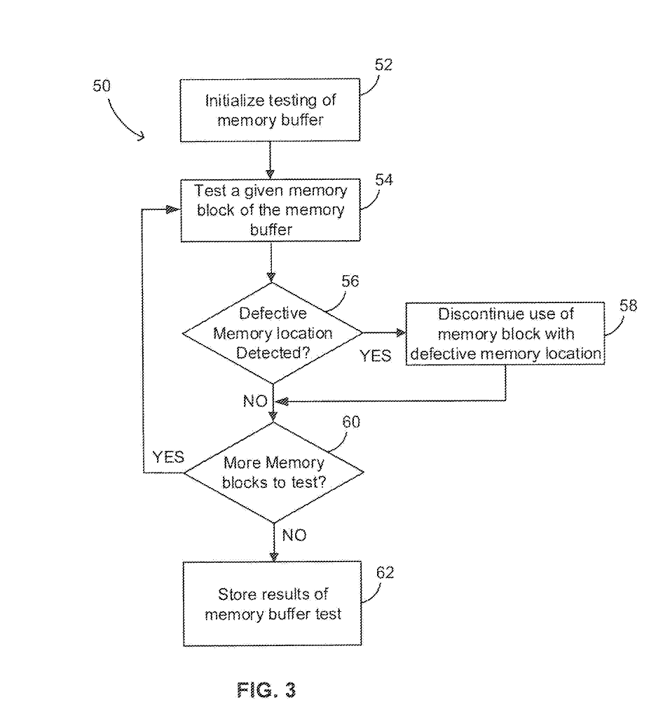

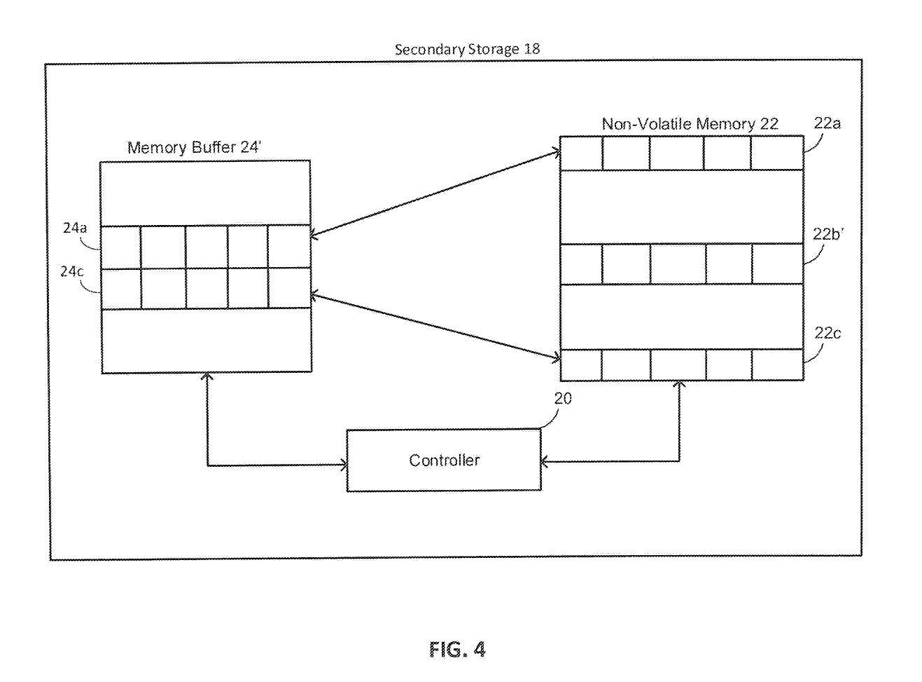

Reference is now made to FIGS. 3 and 4. FIG. 3 shows a flowchart of an example embodiment of a memory testing method 50 for testing the memory buffer of the secondary storage device for memory errors. FIG. 4 shows a block diagram of an example usage scenario for testing the memory buffer 24 of the secondary storage device 18 for errors and dealing with the errors in which the arrows indicate data flow. In particular, FIG. 4 shows an example of how the overall memory space of the memory buffer 24 may be altered in order to relieve problems caused by failures or defective memory locations in a given memory block inside the memory buffer 24 of the secondary storage device 18.

The memory testing method 50 begins at act 52 where a test of the memory buffer 22 is initialized. The initialization may include setting various parameters such as, but not limited to, which memory blocks of the memory buffer 22 will be tested, which sequence these memory blocks will be tested in and what type of testing may be used to test these memory blocks. Other test options that may be initialized include, but are not limited to, how often to test, which test patterns to use, and what threshold is used to find memory errors. For example, the memory testing may be initialized so that all memory blocks of the memory buffer 24 are scanned and analyzed for errors in succession. For example, for the usage scenario shown in FIG. 2, memory blocks 24a, 24b and 24c may be scanned in succession.

In at least some embodiments, the testing may occur when one or more of the following conditions are true: an idle stage is detected by the controller 20, when there have been no activities for the memory buffer 24 for the last X seconds, when there are low CPU utilizations (e.g., when the CPU is considered to be at 20% utilization (or below) or when the computing system is operating on AC power). For example, these conditions may allow for background testing of the memory buffer 24 that won't noticeably affect the operation of the computing system 10 by taking advantage of “system idle time” (e.g., when no programs are running) to hide testing.

At act 54 of the method 50, at least one memory block of the memory buffer 24 is tested to see if it includes a defective memory location. Continuing the example of FIG. 2, at act 56, the memory location 24b will be found to have a defective memory location shown by the asterisk. The testing may comprise using logical pattern tests (as for example March tests or shift tests) or retention tests (to see how long the values are stored in memory without requiring refreshing).

In at least one embodiment, the testing may comprise using logical test patterns. For example, the binary value ‘0’ or the binary value ‘1’ may be written to certain or all memory cells in a memory block and then these memory cells may be read to determine if the data that is read is the same as the data that was meant to be written in these memory cells. In other cases, more complex patterns of logical values may be written to the memory cells of the memory block being tested and then read to see if the stored logical values are the same as the logical values that were sent to the memory block for storage.

At act 58, the memory testing method 50 may discontinue use of a given memory block of the memory buffer 24 if a defective memory location error is detected for the given memory block. The exclusion of memory blocks with memory failures or defective memory locations from the usable memory space of the memory buffer 24 allows avoiding corruption of data inside the non-volatile memory 22. Discontinuing use of the given memory block having a defective memory location may comprise removing the given memory block containing the defective memory location from a list of accessible memory blocks for the memory buffer 24. The list of accessible memory blocks may be stored in the non-volatile memory 22. FIG. 4 depicts a usable memory space of the memory buffer 24, in which the memory block 24b has been excluded from the usable memory space of the memory buffer 24 after the defective memory location in the memory block 24b was detected.

Alternatively, rather than having a list of accessible memory blocks that may be used for the memory buffer 24, there may be a list of inaccessible memory blocks that may not be used for the memory buffer 24. This embodiment may result in less storage space since the list of accessible memory blocks is most likely larger than the list of inaccessible memory blocks. These lists include the memory addresses of the corresponding memory blocks.

In an example embodiment, the controller 20 may perform the exclusion of the memory block 24b from the usable memory space of the memory buffer 24 in the following manner. The memory buffer 24 may contain a mapping table that maps memory blocks of the memory buffer 24 to memory blocks of the non-volatile memory 22. One way to perform the exclusion is to remove the reference to the memory block 24b of the memory buffer 24 from the mapping table. Another way to make the exclusion is to mark the reference to the memory block 24b in the mapping table as the most recently used memory block and to map the memory block 24b to a non-existent memory block of the non-volatile memory 22. In this case the content of the memory block 24b is never sent back to the non-volatile memory 22 and the memory block 24b doesn't contain any portion of data from the non-volatile memory 22 of the secondary storage device.

In at least some embodiments, when memory blocks with defective memory cells are found in the memory buffer 24 of the secondary storage device 18, the CPU 12 may also be notified by the controller 20.

In at least some embodiments, when the CPU 12 is notified of memory blocks with defective memory cells in the memory buffer 24 of the secondary storage device 18, then the list of defective memory cells may be stored in the main memory 14 and/or in some other memory element.

At act 60, the memory testing method 50 determines whether there are more memory blocks of the memory buffer 24 that need to be tested. If the determination at act 60 is true, then the memory testing method 50 goes to act 54 to test the next memory block of the memory buffer 24.

If the determination at act 60 is not true and all of the memory blocks of the memory buffer 24 that require testing have been tested, then the memory testing method 60 moves to act 62 where the results of the memory buffer test are stored. For example, the test results may be a list of memory addresses that identify defective memory locations in at least one memory block of the memory buffer 24 may be stored in the non-volatile memory 22 of the secondary storage device 18. The test results data may be stored in the table which is stored in the non-volatile memory 22. The test results may be stored in other memory element but the test results will be lost when the computing system is turned off if these memory elements are not non-volatile memory.

In at least one example embodiment, the memory buffer testing operation may occur during the powering up of the computing system 10. After the memory buffer testing operation, the computing system 10 may then exclude defective memory locations as determined from the current memory testing operation, or as determined from prior memory testing operations. Other times when the buffer memory test may be performed include when the computing system 10 is under-utilized and/or not using a battery.

In at least one example embodiment, the memory buffer testing operation may be performed by the controller 20 of the secondary storage device 18. For instance, the exclusion of memory blocks having defective memory locations from the usable memory space of the memory buffer 24 may be performed by the controller 20. In addition, the defective memory locations in the memory buffer 24 or the memory blocks in the memory buffer 24 having defective memory locations may be stored or recorded into the non-volatile memory 22 by the controller 20. Firmware may be used to configure the controller 20 to perform the acts of testing memory blocks, detecting memory blocks with defective memory locations or memory errors and discontinuing use of the defective memory blocks.

Alternatively, in at least one example embodiment, the memory buffer testing operation may be performed by the CPU 12. In this case the CPU 12 may write and read logical values into memory blocks of the memory buffer 24 and then compare the results of the read operations to the logical values used for the write operations.

In at least one example embodiment, the memory blocks in the memory buffer 24 that have been found to have defective memory cells may be re-tested to determine if the problem with the defective memory cells is temporary or intermittent. This may be done by using thresholds in the settings. The threshold (T) may be a predefined proportion of the number of times (D) in which a memory cell of the memory buffer 24 is found to be defective in a certain number of tests (N). A hard failure is a repeated failure in which a defective memory cell in the memory buffer 24 is always found to have an error. A soft failure is an unrepeated failure, which can happen only for some conditions. For example, soft failures include failures that may happen only for some test patterns and don't happen for other test patterns. For example, when a cell with a binary value ‘0’ is surrounded by cells with a binary value ‘1’, this may cause leakage causing the memory error. Another example of soft failure is a memory error caused by the internal power/signal noise during the normal operation of the memory. Alternatively, a soft failure may be when the number of times the cell is found to be defective (D) is less than the threshold (T) when performing N tests. If the problem is temporary, then the memory block may be determined to be good enough to be used again and removed from the list of memory blocks having a defective memory cell in the test results table stored in the non-volatile memory 22.

At least one of the example embodiments described herein result in at least one technological improvement for the operation of a computing system such as, but not limited to, making computer memory in a secondary storage device more reliable, reducing the number of computer crashes, and avoiding the loss of important information.

It should be noted that in at least one of the example embodiments described in accordance with the teachings herein that the memory buffer 24 may be tested at power up of the computing system 10 and testing at this time may reduce the possibility of memory failures during operation of the computing system 10.

It should be noted that in at least one of the example embodiments described in accordance with the teachings herein that upon power up of the computing system 10, the previously stored list of bad memory blocks may be accessed and excluded from the list of accessible memory blocks during the current operation of the computing system 10. Accordingly, the list of bad memory blocks may be tracked and modified during the operation of the computing system 10 regardless of whether it is shut down and powered back up.

While the applicant's teachings described herein are in conjunction with various embodiments for illustrative purposes, it is not intended that the applicant's teachings be limited to such embodiments. On the contrary, the applicant's teachings described and illustrated herein encompass various alternatives, modifications, and equivalents, without departing from the embodiments described herein, the general scope of which is defined in the appended claims.

1. A method of increasing reliability of a secondary storage device used with a computing system where the secondary storage device contains a memory buffer, a controller, and non-volatile memory, the method comprising:
initializing a test of the memory buffer;
testing at least one memory block of the memory buffer;
discontinuing use of a given memory block of the memory buffer if a defective memory location is detected for the given memory block; and
storing test results for the memory buffer.

2. The method of claim 1, wherein discontinuing use of the given memory block having a defective memory location comprises removing the given memory block containing the defective memory location from a list of accessible memory blocks for the memory buffer and storing the list in the buffer memory and/or the non-volatile memory of the secondary storage device.

3. The method of claim 2, wherein discontinuing use of the given memory block having a defective memory location comprises adding the given memory block to a list of inaccessible memory blocks for the memory buffer and storing the list of inaccessible memory blocks in the buffer memory and/or the non-volatile memory of the secondary storage device.

4. The method of claim 1, wherein the acts of testing, detecting and discontinuing use are performed by the controller of the secondary storage device.

5. The method of claim 4, wherein firmware used by the controller is configured to perform the acts of testing, detecting and discontinuing use.

6. The method of claim 1, wherein the memory buffer comprises a mapping table that maps memory blocks of the memory buffer to memory blocks of the non-volatile memory and the method further comprises removing a reference to memory blocks having defective memory locations from the mapping table.

7. The method of claim 1, wherein the memory buffer comprises a mapping table that maps memory blocks of the memory buffer to memory blocks of the non-volatile memory and the method further comprises marking references in the mapping table to memory blocks having defective memory locations as being the most recently used memory blocks and mapping the memory blocks having defective memory locations to a non-existent memory block of the non-volatile memory.

8. A secondary storage device for providing memory storage space for a computing system, wherein the secondary storage device comprises:
a non-volatile memory configured to store data;
a memory buffer coupled to the non-volatile memory and a main memory of the computing system, the memory buffer being configured to act as a disk cache between the non-volatile memory and main memory of the computing system; and
a controller coupled to the non-volatile memory and the memory buffer, the controller being configured to test the memory buffer for errors by initializing a test of the memory buffer; testing at least one memory block of the memory buffer; discontinuing use of a given memory block of the memory buffer if a defective memory location is detected for the given memory block; and storing test results for the memory buffer.

9. The secondary storage device of claim 8, wherein the controller is configured to discontinue use of the given memory block having a defective memory location by removing the given memory block containing the defective memory location from a list of accessible memory blocks for the memory buffer and storing the list in the buffer memory and/or the non-volatile memory of the secondary storage device.

10. The secondary storage device of claim 8, wherein discontinuing use of the given memory block having a defective memory location comprises adding the given memory block to a list of inaccessible memory blocks for the memory buffer and storing the list of inaccessible memory blocks in the buffer memory and/or the non-volatile memory of the secondary storage device.

11. The secondary storage device of claim 8, wherein the memory buffer comprises a mapping table that maps memory blocks of the memory buffer to memory blocks of the non-volatile memory and the controller is configured to remove the reference to memory blocks having defective memory locations from the mapping table.

12. The secondary storage device of claim 8, wherein the memory buffer comprises a mapping table that maps memory blocks of the memory buffer to memory blocks of the non-volatile memory and the controller is configured to mark references in the mapping table to memory blocks having defective memory locations as being the most recently used memory blocks and mapping the memory blocks having defective memory locations to a non-existent memory block of the non-volatile memory.

13. The secondary storage device of claim 8, wherein the non-volatile memory comprises at least one of flash memory, a solid-state drive and a hard drive.

14. A computing system comprising:
a Central Processing Unit (CPU) to control the computing system;
a main memory element coupled to the CPU to store information used by the CPU during the operation of the computing system; and
a secondary storage device for providing memory storage space for a computing system, wherein the secondary storage device comprises:
a non-volatile memory configured to store data;
a memory buffer coupled to the non-volatile memory and a main memory of the computing system, the memory buffer being configured to act as a disk cache between the non-volatile memory and main memory of the computing system; and
a controller coupled to the non-volatile memory and the memory buffer, the controller being configured to test the memory buffer for errors by initializing a test of the memory buffer; testing at least one memory block of the memory buffer; discontinuing use of a given memory block of the memory buffer if a defective memory location is detected for the given memory block; and storing test results for the memory buffer.

15. The computing system of claim 14, wherein discontinuing use of the given memory block having a defective memory location comprises adding the given memory block to a list of inaccessible memory blocks for the memory buffer and storing the list of inaccessible memory blocks in the buffer memory or the non-volatile memory of the secondary storage device.

16. A computer readable medium comprising a plurality of instructions that are executable by a controller of a secondary storage device for increasing reliability of the secondary storage device, the secondary storage device further comprising a memory buffer and non-volatile memory both coupled to the controller, wherein the plurality of instructions implement a method comprising:
initializing a test of the memory buffer;
testing at least one memory block of the memory buffer;
discontinuing use of a given memory block of the memory buffer if a defective memory location is detected for the given memory block; and
storing test results for the memory buffer in the non-volatile memory, the test results being used by the controller to avoid defective memory locations for future read and write operations.

17. The computer readable medium of claim 16, wherein discontinuing use of the given memory block having a defective memory location comprises removing the given memory block containing the defective memory location from a list of accessible memory blocks for the memory buffer and storing the list in the buffer memory and/or the non-volatile memory of the secondary storage device.

18. The computer readable medium of claim 16, wherein discontinuing use of the given memory block having a defective memory location comprises adding the given memory block to a list of inaccessible memory blocks for the memory buffer and storing the list of accessible memory blocks in the buffer memory and/or the non-volatile memory of the secondary storage device.

19. The computer readable medium of claim 17, wherein the acts of testing, detecting and discontinuing use are performed by the controller of the secondary storage device.

20. The computer readable medium of claim 17, wherein the memory buffer comprises a mapping table that maps memory blocks of the memory buffer to memory blocks of the non-volatile memory and the method further comprises removing the reference to memory blocks having defective memory locations from the mapping table.

21. The computer readable medium of claim 17, wherein the memory buffer comprises a mapping table that maps memory blocks of the memory buffer to memory blocks of the non-volatile memory and the method further comprises marking references in the mapping table to memory blocks having defective memory locations as being the most recently used memory blocks and mapping the memory blocks having defective memory locations to a non-existent memory block of the non-volatile memory.
